(19) United States
(12) Patent Application Publication
(10) Pub. No.: US 2020/0272297 A1
(43) Pub. Date: Aug. 27, 2020

(54) TOUCH PANEL AND CONTROL METHOD OF TOUCH PANEL

(71) Applicant: SHARP KABUSHIKI KAISHA, Sakai City (JP)

(72) Inventor: IKUO SHIMASAKI, Sakai City (JP)

(21) Appl. No.: 16/745,244

(22) Filed: Jan. 16, 2020

(30) Foreign Application Priority Data
Feb. 21, 2019 (JP) 2019-029427

(51) Int. Cl. G06F 3/041; G06F 3/0488; H01L 41/09

(52) U.S. Cl. CPC G06F 3/04162; H01L 41/09; G06F 3/04886; G06F 3/0412

(57) ABSTRACT

A touch panel includes a display device, an input device, a vibration device, and a controller. The input device accepts a touch operation made with respect to the display device. The vibration device vibrates the display device. The controller controls the display device, the input device, and the vibration device. The controller includes a display controller and a vibration controller. The display controller displays a predetermined keyboard image on the display device. When the most recent touch operation is a home position search operation, the vibration controller selects, based on a relative positional relationship between the touch position of this touch operation and a first home position set on the keyboard image, a vibration pattern from among a plurality of vibration patterns that di tier according to the relative positional relationship as a first vibration pattern, and vibrates the display device via the vibration device according to the first vibration pattern.

### BACKGROUND OF THE INVENTION

### Field of the Invention

The present invention relates to a touch panel, and more specifically, to a touch panel used in a multifunction peripheral or the like. Furthermore, the present invention relates to a control method of a touch panel.

### Description of the Background Art

There is a demand for a function referred to as a virtual keyboard function or a touch panel keyboard function that displays a keyboard image on a touch panel having a touch input function, and simulates a key input operation by a touch operation.

In relation to the above, Japanese Unexamined Patent Application Publication No. 5,575,027 discloses an invention related to a display-integrated coordinate input device, This display-integrated coordinate input device has a coordinate input device and an image display device which are integrally formed. Further, it is a touch panel-type device to which a plurality of coordinates can be input at the same time. This display-integrated coordinate input device includes a first device to a seventh device as described below. The first device detects an input coordinate when an input is made to the coordinate input device. The second device holds the coordinate information that has been pointed to when a plurality of points are input to the coordinate input device. The third device determines whether a virtual keyboard function has already been started in the display-integrated coordinate input device. If the virtual keyboard function has not been started, the fourth device determines whether a request to start the virtual keyboard function has been made using the number of coordinates that have been pointed to on the coordinate input device, and the position information thereof. If it is determined that a request to start the virtual keyboard function has been made, the fifth device calculates a display position and a display size of the virtual keyboard that has been started using the information that has been input to the coordinate input device. The sixth device creates an image of the virtual keyboard at the display position and having the display size. The seventh device displays the created image on the image display device. The third device, which determines whether a request has been made to start the virtual keyboard function, includes an eighth device to an eleventh device as described below. If the number of points that has been input to the coordinate input device is ten, the eighth device excludes two arbitrary points among the ten points to calculate an approximate straight line from the contact positions of the remaining eight points. The ninth device takes all of the combinations of eight points, which exclude two arbitrary points, to calculate the respective sums of distances from each of the eight contact positions to the approximate straight line. The tenth device obtains a combination that excludes the contact position of the thumb of the left hand and the contact position of the thumb of the right hand from the combination having the smallest sum of distances. The eleventh device determines that an input is a request to start the virtual keyboard function when the distances from the eight contact positions of the obtained combination to the approximate straight line are all within a predetermined distance.

### SUMMARY OF THE INVENTION

In conventional virtual keyboard functions using a touch panel, in order to confirm the position on the touch panel at which the user performed a touch input, it is necessary for the recognition to be performed using at least one of the sense of vision and the sense of hearing by changing the color of the display or generating a sound at the time of a touch input. Further, the entire area of a touch panel surface is generally flat. Therefore, it is problematic or impossible for the user to perform recognition of the contours of the keys included in the keyboard image with the sense of touch using the fingertips. For this reason, it has been difficult to realize touch typing, in which the user performs key inputs without looking at a keyboard or an image thereof, by using the virtual keyboard function of a touch panel. Therefore, high-speed key inputs as in the case of touch typing have been difficult to perform using the virtual keyboard function of a touch panel. As a solution, a physical keyboard needs to be prepared separately from the touch panel.

The present invention has an object of providing a touch panel that facilitates touch typing and a control method of a touch panel. Other problems and novel features will become apparent from the description of the present specification and the accompanying drawings.

Hereinafter, the means for solving the problems described above will be described using the numerals used under the (Description of the Preferred Embodiments). These numerals are provided to clarify the correspondence between the (Claims) and the (Description of the Preferred Embodiments). However, the numerals should not be used for interpreting the technical scope of the invention described in the (Claims).

A touch panel (10) according to the present invention includes a display device (42), an input device (41), a vibration device (43), and a controller (20). The input device (41) accepts a touch operation made with respect to the display device (42). The vibration device (43) vibrates the display device (42). The controller (20) controls the display device (42), the input device (41), and the vibration device (43). The controller (43) includes a display controller (22) and a vibration controller (23). The display controller (22) displays a predetermined keyboard image (100) on the display device (42). When a most recent touch operation is a home position search operation, the vibration controller (23) selects, based on a relative positional relationship between a touch position on the display device (42) at which the most recent touch operation is received and a first home position set on the keyboard image, a vibration pattern from among a plurality of vibration patterns that differ according to the relative positional relationship as a first vibration pattern, and vibrates the display device (42) via the vibration device (43) according to the first vibration pattern.

A control method of a touch panel (10) according to the present invention is a control method of a touch panel (41) including a display device (42), an input device (41) that accepts a touch operation with respect to the display device (42), and a vibration device (43) that vibrates the display device (42). The control method of the touch panel (41) includes a keyboard image displaying step (S25) and a vibrating step (S35). The keyboard image displaying step (S25) is a step for displaying a predetermined keyboard image (100) on the display device (42). The vibration step (S35) is a step for selecting, when a most recent touch operation is a home position search operation, based on a relative positional relationship between a touch position on the display device (42) at which the most recent touch operation is received and a first home position set on the keyboard image (100), a vibration pattern from among a plurality of vibration patterns that differ according to the relative positional relationship as a first vibration pattern, and vibrating the display device (42) via the vibration device (43) according to the first vibration pattern.

According to the present invention, a touch panel that facilitates touch typing and a control method of a touch panel are provided.

### BRIEF DESCRIPTION OF THE DRAWINGS

FIG. 1 is a perspective view showing a configuration example of a multifunction peripheral according to an embodiment of the present invention.

FIG. 2 is a block circuit diagram showing a configuration example of a touch panel according to an embodiment of the present invention.

FIG. 3A is a perspective view showing a configuration example of an input/output (I/O) module according to an embodiment of the present invention.

FIG. 3B is a perspective view showing the I/O module in FIG. 3A from another direction.

FIG. 4A is a block circuit diagram showing a configuration example of a controller according to an embodiment of the present invention.

FIG. 4B is a block circuit diagram functionally showing a configuration example of a controller according to an embodiment of the present invention.

FIG. 5A is a flowchart showing an example of a control method of a touch panel according to an embodiment of the present invention.

FIG. 5B is a sub-flowchart showing a configuration example of step S01 within the flowchart in FIG. 5A.

FIG. 5C is a sub-flowchart showing a configuration example of step S02 within the flowchart in FIG. 5A.

FIG. 5D is a sub-flowchart showing a configuration example of step S03 within the flowchart in FIG. 5A.

FIG. 6A is a diagram showing an example of reference positions acquired according to an embodiment of the present invention.

FIG. 6B is a diagram showing a display example of a touch panel according to an embodiment of the present invention.

FIG. 7A is a diagram showing another example of reference positions acquired according to an embodiment of the present invention.

FIG. 7B is a diagram showing another example an adjusted keyboard image displayed according to an embodiment of the present invention.

FIG. 8A is a diagram showing yet another example of reference positions acquired according to an embodiment of the present invention.

FIG. 8B is a diagram showing yet another example an adjusted keyboard image displayed according to an embodiment of the present invention.

FIG. 9A is a diagram showing yet another example of reference positions acquired according to an embodiment of the present invention.

FIG. 9B is a diagram showing yet another example an adjusted keyboard image displayed according to an embodiment of the present invention.

FIG. 10A is a diagram showing yet another example of reference positions acquired according to an embodiment of the present invention.

FIG. 10B is a diagram showing yet another example an adjusted keyboard image displayed according to an embodiment of the present invention.

### DESCRIPTION OF THE PREFERRED EMBODIMENTS

An embodiment for implementing touch panel and a control method of a touch panel according to the present invention will be described below with reference to the accompanying drawings.

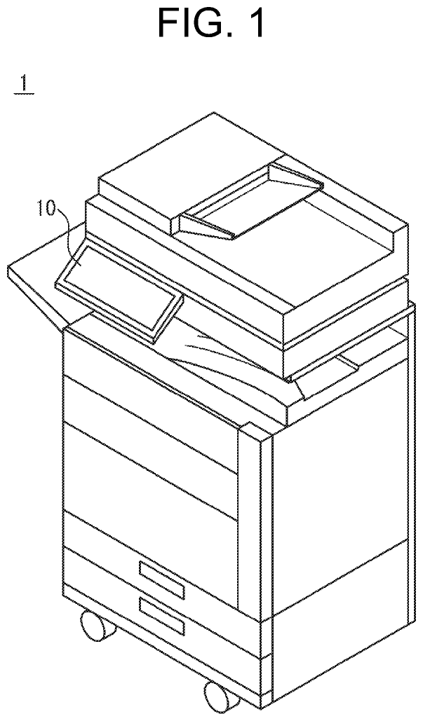

FIG. 1 is a perspective view showing a configuration example of a multifunction peripheral 1 according to an embodiment of the present invention. The multifunction peripheral 1 includes a touch panel 10. The touch panel 10 is capable of displaying various information relating to the multifunction peripheral 1. Furthermore, various functions included in the multifunction peripheral 1 can be realized by an operator performing a touch operation with respect to the touch panel M. The other configurations of the multifunction peripheral 1 have little direct relation to the present invention, and therefore, a detailed description is omitted here.

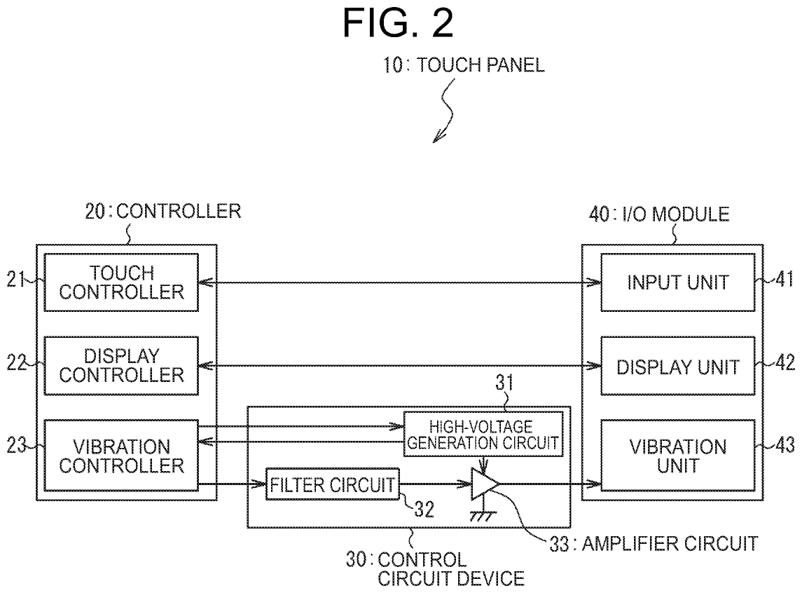

A configuration example of the touch panel 10 in FIG. 1 will be described referring to FIG. 2. FIG. 2 is a block circuit diagram showing a configuration example of a touch panel 10 according to an embodiment of the present invention. The touch panel 10 in FIG. 2 includes a controller 20, a control circuit device 30, and an I/O module 40. The controller 20 is configured to control the I/O module 40 and the control circuit device 30. The control circuit device 30 is configured to generate various signals for controlling a vibration output. The I/O module 40 is configured to be capable of receiving touch operation inputs, and providing display and vibration outputs.

The controller 20 includes a touch controller 21, a display controller 22, and vibration controller 23. The control circuit device 30 includes a high-voltage generation circuit 31, a filter circuit 32, and an amplifier circuit 33. The I/O module 40 includes an input unit 41, a display unit 42, and a vibration unit 43. A plurality of vibration units 43 may be provided. Hereinafter, both single and multiple vibration units 43 may be collectively referred to as a vibration unit group 43. The vibration unit 43 may include, for example, a piezoelectric element, a motor, or an electromagnetic coil that vibrates according to the amplitude, waveform, or frequency of an applied electric signal.

The touch controller 21 and the input unit 41 are electrically connected. The display controller 22 and the display unit 42 are electrically connected. The vibration controller 23 and the high-voltage generation circuit 31 are electrically connected, The vibration controller 23 and the filter circuit 32 are electrically connected. The high-voltage generation circuit 31 and the amplifier circuit 33 are electrically connected, The filter circuit 32 and the amplifier circuit 33 are electrically connected. The amplifier circuit 33 and the vibration unit 43 are electrically connected.

The input unit 41 is configured to accept a touch operation made by an external user, generate a position information signal that indicates a touch position at which the touch operation is received on the surface, and then transmit the signal to the touch controller 21.

The display unit 42 is configured to be capable of displaying an arbitrary image under the control of the display controller 22.

The vibration unit group 43 is configured to be capable of vibrating the input unit 41 according to an arbitrary vibration pattern under the control of the vibration controller 23. The vibration controller 23 may select a vibration pattern from among a plurality of vibration patterns in which, for example, a vibration waveform, a vibration amplitude, and a vibration frequency have been appropriately combined.

The control circuit device 30 is configured to be capable of generating an electrical signal for vibrating the vibration unit group 43 according to a predetermined vibration pattern under the control of the vibration controller 23. In one configuration example, the high-voltage generation circuit 31 generates a predetermined voltage under the control of the vibration controller 23. The filter circuit 32 receives a pre-conversion signal from the vibration controller 23, converts the pre-conversion signal according to its own filter characteristics, and outputs a post-conversion signal obtained as a result of the conversion. Here, the pre-conversion signal may, for example, be a pulse width modulation (PWM) having a predetermined amplitude, a predetermined frequency, and a predetermined duty ratio. Furthermore, the post-conversion signal may be an arbitrary signal having a predetermined waveform and a predetermined amplitude. The amplifier circuit 33 generates a vibration control signal based on the voltage originating from the high-voltage generation circuit 31 and the post-conversion signal originating from the filter circuit 32, and outputs a vibration control signal to the vibration unit group 43. Here, the vibration control signal may be a signal obtained by amplifying the amplitude of the post-conversion signal. Moreover, a plurality of vibration control signals may be generated in a plurality of vibration units 43 and then output at a plurality of timings.

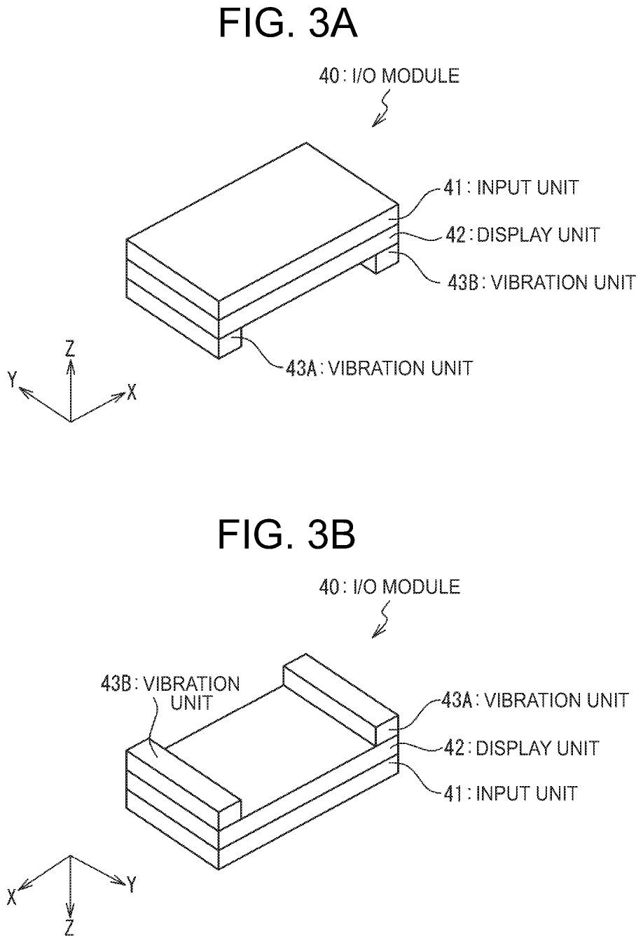

A more specific configuration example of the I/O module 40 in FIG. 2 will be described with reference to FIG. 3A and 3B. FIG. 3A is a perspective view showing a configuration example of the I/O module 40 according to an embodiment of the present invention. FIG. 3B is a perspective view showing the 110 module 40 in FIG. 3A from another direction. The module 40 in FIG. 3A and FIG. 3B includes an input unit 41, a display unit 42, a first vibration unit 43A, and a second vibration unit 43B. Hereinafter, when the first vibration unit 43A and the second vibration unit 43B are not distinguished, they are simply referred to as a vibration unit 43 or a vibration unit group 43, Although the total number of vibration units 43 in the configuration example in FIG. 3A and FIG. 3B is two, this is only an example and does not limit the present invention.

In the Cartesian coordinates XYZ shown in FIG. 3A and FIG. 3B, the input unit 41 has a substantially rectangular parallelepiped shape, and the respective sides of the rectangular parallelepiped is parallel to the X axis, the Y axis, or the Z axis. Here, the four shortest sides of the rectangular parallelepiped are parallel to the Z axis, and the four longest sides of the rectangular parallelepiped are parallel to the X axis. Hereinafter, the dimension of the rectangular parallelepiped in the Z-axis direction is referred to as the thickness of the input unit 41. Furthermore, the dimensions of the rectangular parallelepiped in the X-axis direction and the Y-axis direction are respectively referred to as the long side length and the short side length of the input unit 41. In other words, the shape of the input unit 41 is a thin rectangular plate shape.

In the example in FIG. 3A and FIG. 3B, the display unit 42 has a substantially rectangular parallelepiped shape in a similar fashion to the input unit 41. In other words, the shape of the display unit 42 is also a thin rectangular plate shape.

The input unit 41 and the display unit 42 are stacked in the thickness direction. Here, the input unit 41 is arranged so as to cover the surface of the display unit 42. That is to say, a user is capable of viewing the display of the display unit 42 via the input unit 41. Therefore, it is preferable for at least the portion of the input unit 41 that covers the display unit 42 to be as transparent as possible.

As a result of arranging the input unit 41 and the display unit 42 in this manner, a so-called touch panel keyboard function can be realized using the I/O module 40. That is to say, because the user performs a touch operation on an area of the input unit 41 corresponding to an area which is displaying an arbitrary image on the display unit 42, the user is able to perform the operation while obtaining the sense of performing the touch operation with respect to the image. Further, by displaying an image of a keyboard that includes a plurality of keys on the display unit 42, when the user performs a touch operation on the area of the input unit 41 that corresponds to an area which is displaying the keys, the user is able to perform the operation while obtaining the sense of performing the touch operation with respect, to the keys.

As described below, touch typing is generally difficult when using a touch panel keyboard function. Touch typing is a technique in Which the user performs key inputs without looking at the keyboard. When performing touch typing, a specific key on the keyboard is defined as a home position of each finger, and the user performs the action of placing each of the fingers on the home position keys. The user is capable of recognizing the home positions and surrounding keys by feeling for protrusions and the end positions on the keys, that is to say, by only using the sense of touch and not relying on the sense of vision. On the other hand, in a touch panel keyboard function, because the surface of the input unit 41 is a uniform flat surface, there is a tendency for the user to lack the information usually obtained by the sense of touch.

Therefore, the touch panel 10 according to the present invention is provided with the vibration unit group 43 which vibrates the input unit 41. This assists with touch typing using the touch panel keyboard function, and inhibits erroneous inputs. More specifically, the vibration unit group 43 vibrates the input unit 41 with a different vibration pattern according to the distance from the most recent touch position, where a touch operation is made on the input unit 41 by a user's finger, to the home position, which represents a reference position. As a result, the user is capable of estimating by haptic feedback how far the position of the user's finger touching the input unit 41 is from the home position. Furthermore, the position of two or more home positions may also be estimated by the sense of touch of the fingers of the left and right hands by causing the two or more vibration units 43 to respectively vibrate the input unit 41 with at least one of different vibration patterns and timings.

Therefore, in the example in FIG. 3A and FIG. 3B, the two vibration units 43A and 43B are disposed as far apart as possible in the longitudinal direction of the input unit 41. However, the shape and positional relationship of the input unit 41, the display unit 42, and the vibration unit group 43 shown in FIG. 3A and FIG. 3B are merely an example, and do not limit the present invention.

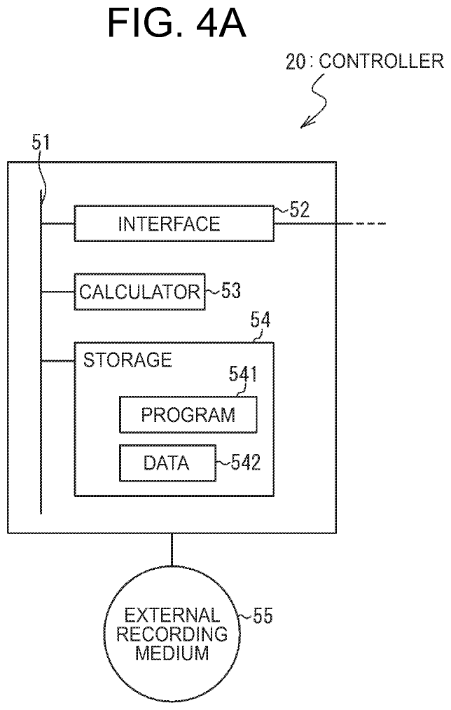

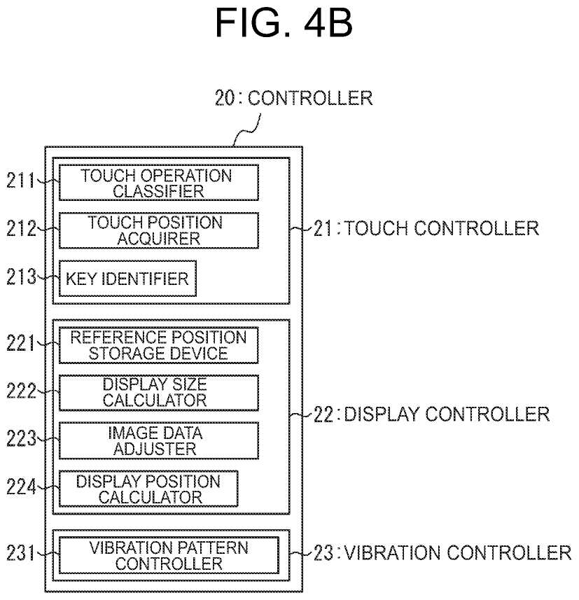

A configuration example of the controller 20 will be described with reference to FIG. 4A and 4B. FIG. 4A is a block circuit diagram showing a configuration example of a controller 20 according to an embodiment of the present invention. FIG. 4B is a block circuit diagram functionally showing a configuration example of a controller 20 according to an embodiment of the present invention.

In the block circuit diagram in FIG. 4A, the controller 20 includes a bus 51, an interface 52, a calculator 53, and a storage 54. In other words, the controller 20 may be configured as a computer. The bus 51 is electrically connected to the interface 52, the calculator 53, and the storage 54, and enables mutual communication between the interface 52, the calculator 53, and the storage 54. The interface 52 is configured to perform communication with an external device. The calculator 53 is configured to realize various functions of the controller 20 by reading and executing programs 541 stored in the storage 54. The storage 54 stores various programs 541, and various data 542 necessary for executing the programs 541. The programs 541 may be supplied via an external recording medium 55.

In the block circuit diagram in FIG. 4B, the controller 20 includes a touch controller 21, a display controller 22, and vibration controller 23. The touch controller 21 includes an operation classifier 211, a touch position acquirer 212, and a key identifier 213. The display controller 22 includes a reference position storage device 221, a display size calculator 222, an image data adjuster 223, and a display position calculator 224. The vibration controller 23 includes a vibration pattern controller 231. In other words, the controller 20 may be configured as a set of functional blocks realized by a computer.

The operation classifier 211 analyzes and classifies a touch operation performed with respect to the input unit 41. As an example, the operation classifier 211 classifies whether a touch operation is performed for the purpose of a key input, or for the purpose of searching for a home position. The classification is performed based on whether or not the touch operation satisfied a predetermined condition. For example, the classification may be performed based on the touch strength of the touch operation, or performed based on the touch area of the touch operation. As an example, a touch operation whose touch strength exceeds a predetermined threshold may be classified as a key input, and other touch operations may be classified as a search for a home position. As another example, a touch operation whose touch area exceeds a predetermined threshold may be classified as a key input, and other touch operations may be classified as a search for a home position.

The touch position acquirer 212 acquires, based on a control signal transmitted from the input unit 41, the touch position at which a touch operation is performed with respect to the input unit 41. The touch position may be expressed, for example, in the form of a planar Cartesian coordinate. The touch position acquirer 212 is preferably configured to be capable of converting the touch position into a pixel position on the display unit 42.

The key identifier 213 is configured to obtain, based on the touch position at which a touch operation is performed with respect to the input unit 41, the key within the keyboard image displayed on the display unit 42 that corresponds to the touch position.

The reference position storage device 221 stores in the storage 54 the touch position at which a touch operation is performed with respect to the input unit 41 as a reference position to determine the display position and the display size of the keyboard image. Here, the total number of reference positions may be two or more. The reference position storage device 221 may appropriately modify some or all of the reference positions so that the reference positions satisfy a predetermined condition. As an example, it is considered to be preferable for a straight line passing through a first reference position, which corresponds to the “F” key, and a second reference position, which corresponds to the “J” key, to be parallel to the longitudinal direction of the display unit 42 (the X-axis direction in FIG. 3A and FIG. 3B). Therefore, when the angle between the straight line and the longitudinal direction is smaller than a predetermined threshold, the reference position storage device 221 may apply a change that appropriately corrects one or both of the two reference positions so that the angle becomes zero.

The display size calculator 222 calculates the display size of the keyboard image displayed on the display unit 42 based on the reference positions. As an example, among the two reference positions, the first reference position corresponds to the “F” key, and the second reference position corresponds to the “J” key. Assuming that the interval from the first reference position to the second reference position is equal to the interval from the “F” key to the “J” key”, one-third of this interval is equal to the key pitch of the keyboard. The display size of the keyboard image is easily calculated, for example, by a proportional calculation based on the key pitch. If the calculated display size does not fit inside the display area of the display unit 42 because it is too large, the display size calculator 222 may return an error to the display controller 22.

The image data adjuster 223 generates an adjusted keyboard image that has been adjusted to match the calculated display size. In other words, the image data adjuster 223, the display controller 22, or the controller 20 is provided with an original keyboard image in advance, and arc capable of generating the adjusted keyboard image by enlarging or reducing the keyboard image by a predetermined scale. The scale can be calculated, for example, based on a ratio between the calculated display size and the size of the original keyboard image.

The display position calculator 224 calculates the display position at which the adjusted keyboard image is to be displayed on the display unit 42. The display position is, for example, the pixel position of the display unit 42 where the origin GO of the upper-left corner of the adjusted keyboard image is displayed. The display position can be calculated, for example, by a proportional calculation based on the display size of the adjusted keyboard image, and the reference positions of the adjusted keyboard image and the display unit 42. If the adjusted keyboard image does not fit inside the display area of the display unit 42 when an attempt is made to display the adjusted keyboard image at the calculated display position, the display position calculator 224 may return an error to the display controller 22.

The vibration pattern controller 231 generates a control signal that the vibration controller 23 outputs to the control circuit device 30. More specifically, the vibration pattern controller 231 generates a control signal for arbitrarily setting each of the vibration waveform, the vibration amplitude, and the vibration frequency included in the vibration pattern of the vibration of each vibration unit 43.

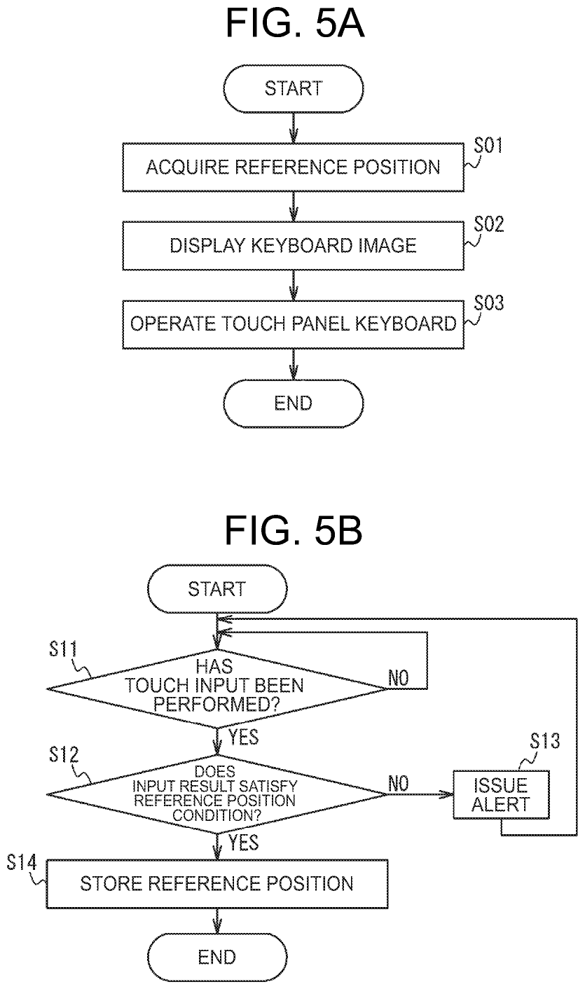

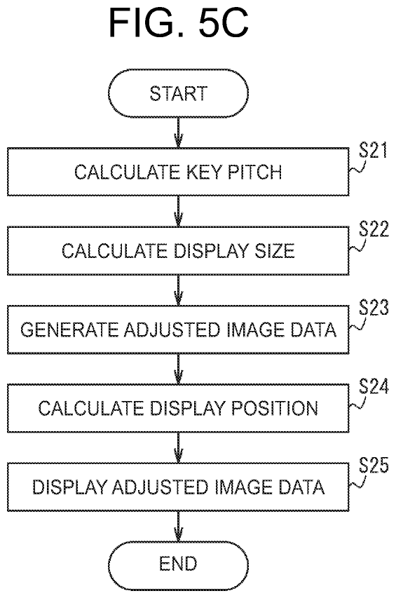

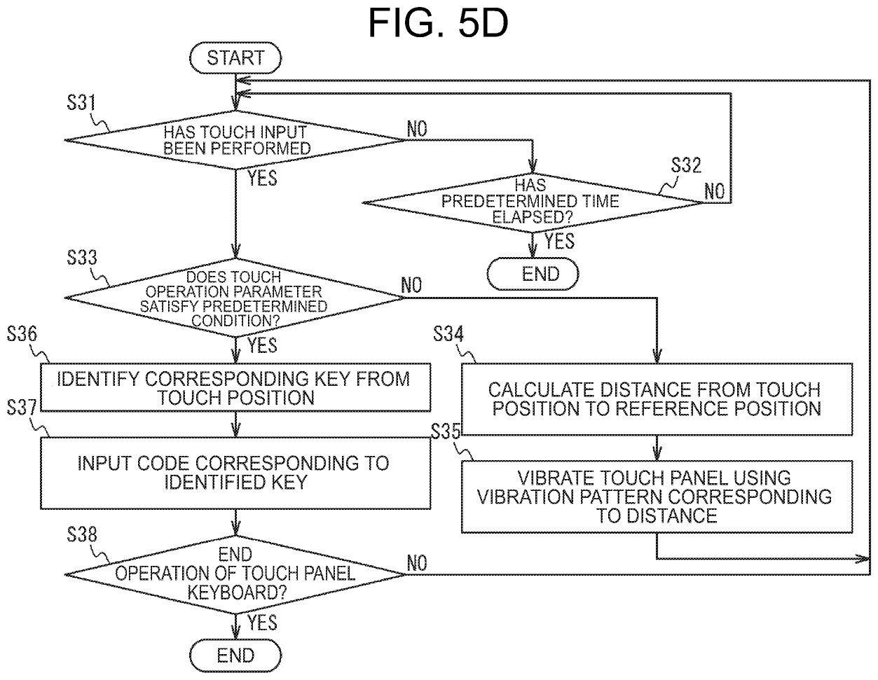

An operation example of the touch panel 10 according to an embodiment of the present invention will be described with reference to FIG. 5A to FIG. 5D. FIG. 5A is a flowchart showing an example of a control method of the touch panel 10 according to an embodiment of the present invention. FIG. 5B is a sub-flowchart showing a configuration example of step S01 within the flowchart of FIG. 5A. FIG. 5C is a sub-flowchart showing a configuration example of step S02 within the flowchart of FIG. 5A, FIG. 5D is a sub-flowchart showing a configuration example of step S03 within the flowchart of FIG. 5A.

The flowchart in FIG. 5A includes a first step S01, a second step S02, and a third step S03. When the flowchart in FIG. 5A starts, the first step S01 is executed.

In the first step S01, acquisition of the reference positions is performed. Here, the reference positions are positions that correspond to home positions for touch typing. In an embodiment of the present invention, the total number of acquired reference positions is two. In this example, the first reference position corresponds to the home position of the forefinger of the left hand. Further, the second reference position corresponds to the home position of the forefinger of the right hand. As an example, on a standard JIS (Japanese Industrial Standard) keyboard, the home position of the forefinger of the left hand corresponds to the “F” key, and the home position of the forefinger of the right hand corresponds to the “J” key. When the first step SOI is executed, the sub-flowchart in FIG. 5B is executed.

The sub-flowchart in FIG. 5B includes a first step S11, a second step S12, a third step S13, and a fourth step S14. When the sub-flowchart in FIG. 5B starts, the first step S11 is executed.

In the first step S11, it is determined by the input unit 41 and the touch controller 21 whether a touch input has been performed. If it is determined in the first step S11 that a touch input has not been performed (NO), the first step S11 is executed again. In contrast, if it is determined that a touch input has been performed (YES), the second step S12 is executed following the first step S11. In other words, the first step S11 is repeatedly executed until a touch input is performed, and the second step S12 is executed after a touch input has been performed.

In the second step S12, it is determined whether the result of the touch operation performed in the first step S11 satisfies a reference position condition. Here, the reference position condition includes at least that the entire keyboard image having a display size based on the reference positions is capable of being displayed at a display position on the display unit 42 which is based on the reference positions. In other words, as a result of calculating the display size and the display position based on the reference positions, one of the conditions to be satisfied by the reference positions is that the entire keyboard image fits inside the frame of the display unit 42 when the keyboard image is displayed on the display unit 42 based on the display size and the display position,. These determinations may be performed, for example, by at least one of the display position calculator 222 and the display size calculator 224.

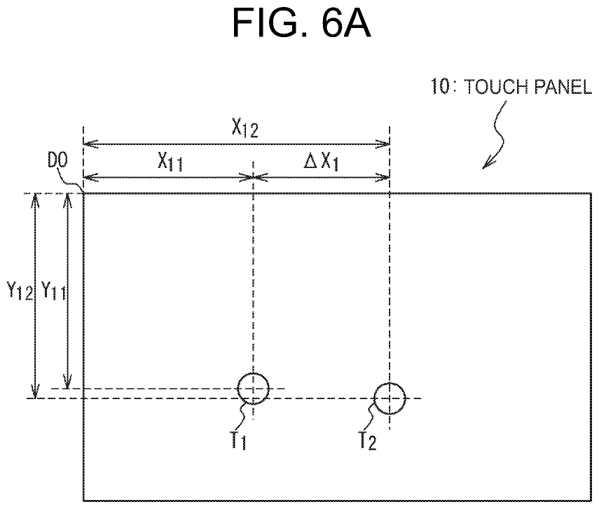

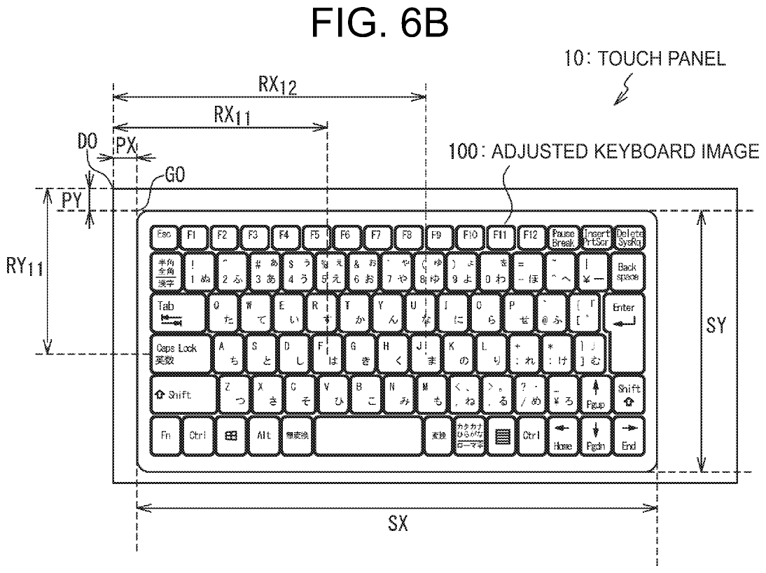

FIG. 6A is a diagram showing an example of the reference positions T₁ and T₂ acquired according to an embodiment of the present invention. In planar coordinates whose origin DO is at the upper-left corner of the touch panel 10, the first reference position T₁ has a horizontal direction (the X-axis direction in FIG. 3A and FIG. 3B) coordinate X₁₁, and a vertical direction (the Y-axis direction in FIG. 3A and FIG. 3B) coordinate Y₁₁. Similarly, the second reference position T₂ has a horizontal direction coordinate X₁₂, and a vertical direction coordinate Y₁₂. In this example, the horizontal direction coordinate X₁₁ of the first reference position T₁ is smaller than the horizontal direction coordinate X₁₂ of the second reference position T₂. Therefore, the first reference position T₁ corresponds to the “F” key, and the second reference position T₂ corresponds to the “J” key.

If it is determined in the second step S12 that the result of the touch input does not satisfy the reference position condition (NO), the third step S13 is executed following the second step S12. This condition may include, for example, that the keyboard image displayed in the second step S02 of FIG. 5A described below fits inside a predetermined area within the display area of the display unit 42. This is because the display size and the display position of the keyboard image calculated in a first step S21 to a fourth step S24 of FIG. 5C described below is calculated based on the reference positions, that is to say, based on the result of the touch input performed in the first step S11 of FIG. 5B. From this perspective, the area inside the display area of the display unit 42 in which a reference position is allowed is considered to be determined in advance. Therefore, for example, this area may be shown filled with a transparent color or the like in the first step S11 of FIG. 5B. As a result, the user can distinguish the locations where touch inputs should be made from the other areas of the display unit 42. In the third step S13, an arbitrary alert is issued indicating that the result of the touch input does not satisfy the reference position condition, and the first step S11 is executed again. On the other hand, if it is determined that the result of the touch input satisfies the reference position condition (YES), the fourth step S14 is executed following the second step S12, In other words, some or all of the first step S 11, the second step S12, and the third step S13 are repeatedly executed until a touch input is performed that satisfies the reference position condition, and the fourth step S14 is executed after a touch input is performed that satisfies the reference position condition.

As described above, in the third step S13, an alert is issued indicating that the result of the touch input does not satisfy the reference position condition. The alert has an object of prompting the user to perform another touch input that satisfies the reference position condition. Therefore, the alert may be realized by displaying an arbitrary character string or image on the display unit 42. For example, when a virtual straight line connecting two touch positions at which touch inputs were performed is not horizontal, or in other words, is not parallel to the horizontal axis direction of the display unit 42, or more specifically, when the angle between the virtual straight line and the horizontal axis direction exceeds a predetermined threshold, an alert may be issued that notifies the user of this fact. For example, when the keyboard image is attempted to be displayed based on two touch positions, and the keyboard image protrudes from a predetermined area of the display unit 42 in one or more of the up, down, left, and right directions, and there is no problem with the distance between the two touch positions, it is preferable for the next two touch positions at which a touch input is performed to be moved in a parallel fashion in the direction opposite to the protruding direction. Therefore, an alert may be issued that notifies the user of this fact. For example, when the keyboard image is attempted to be displayed based on two touch positions, and the keyboard image protrudes from a predetermined area of the display unit 42 in one or more of the up, down, left, and right directions, and it is thought that the cause is due to the two touch positions being too far apart, it is preferable for the next two touch positions at which a touch input is performed to be closer together. Therefore, an alert may be issued that notifies the user of this fact. Alternatively, an alert may be realized by the vibration unit group 43 by generating a vibration having an arbitrary waveform, an arbitrary frequency, and an arbitrary amplitude. In addition, an alert may be realized by playing an arbitrary sound using an audio device such as a speaker (not shown). Alternatively, an alert may be realized using a combination of some or all of these.

In the fourth step S14, the reference position storage device 221 stores the reference positions in the storage 54. More specifically, the position information in the XY coordinates of the input unit 41, which indicates the touch positions at Which the touch input satisfying the reference position condition is performed, may be associated with the reference positions and stored in the storage 54. When the fourth step S14 ends, the sub-flowchart in FIG. 5B also ends, and then the second step S02 of the flowchart in FIG. 5A is executed.

In the second step S02 of the flowchart in FIG. 5A, the display unit 42 displays the keyboard image under the control of the display controller 22. More specifically, when the second step S02 is executed, the sub-flowchart in FIG. 5C is executed.

The sub-flowchart in FIG. 5C includes a first step S21, a second step S22, a third step S23, a fourth step S24, and a fifth step S25. When the sub-flowchart in FIG. 5C starts, the first step S21 is executed.

In the first step S21, calculation of the key pitch is performed, The calculation may be performed by any one of the controller 20, the display controller 22, the display size calculator 222, the image data adjuster 223, or the display position calculator 224. Here, the key pitch generally refers to the interval XY coordinates between the center of two adjacent key's in the among a plurality of keys included in the keyboard. More precisely, the key pitch may include a first key pitch along the Y axis, and a second key pitch along the X axis. As an example, the first key pitch and the second key pitch are each uniform over the entire keyboard, and the two key pitches may also be equal. For example, one third of the distance between the two reference positions stored in the fourth step S14 of FIG. 5B may be set as the first key pitch and the second key pitch. The second step S22 is executed following the first step S21.

In the second step S22, the display size calculator 222 calculates the display size of the keyboard image to be displayed on the display unit 42, The third step S23 is executed following the second step S22.

In the third step S23, the image data adjuster 223 generates an adjusted keyboard image 100 having the calculated display size. The fourth step S24 is executed following the third step S23.

In the fourth step S24, the display position calculator 224 calculates the display position at which the generated adjusted keyboard image is to be displayed on the display unit 42. The fifth step S25 is executed following the fourth step S24,

In the fifth step S25, the display unit 42 displays the adjusted keyboard image 100 at the display position under the control of the display controller 22. FIG. 6B is a diagram showing a display example of the touch panel 10 according to an embodiment of the present invention. In the example in FIG. 6B, the origin GO on the upper-left corner of the adjusted keyboard image 100 is positioned at a horizontal direction coordinate PX and a vertical direction coordinate PY from the origin DO at the upper-left corner of the touch panel 10. Furthermore, in terms of the display size of the adjusted keyboard image 100, the horizontal direction display size is SX, and the vertical direction display size is SY. The horizontal direction coordinate RX₁₁ at the center of the “F” key of the adjusted keyboard image 100 is equal to the horizontal direction coordinate X₁₁ of the first reference position. The vertical direction coordinate RY₁₁ is equal to the average value of the vertical direction coordinate of the first reference position and the vertical direction coordinate Y₁₂ of the second reference position. Similarly, the horizontal direction coordinate RX₁₂ at the center of the “J” key of the adjusted keyboard image 100 is equal to the horizontal direction coordinate X₁₂ of the second reference position, and the vertical direction coordinate RY₁₁ is the same as that of the “F” key. When the fifth step S25 ends, the sub-flowchart in FIG. 5C also ends, and then the third step S03 of the flowchart in FIG. 5A is executed.

In the third step S03 of the flowchart in FIG. 5A, an operation of the touch panel keyboard is performed. More specifically, when the third step S03 is executed, the sub-flowchart in FIG. 5D is executed.

The sub-flowchart in FIG. 5D includes a first step S31, a second step S32, third step S33, a fourth step S34, a fifth step S35, a sixth step S36, a seventh step S37, and an eighth step S38. When the sub-flowchart in FIG. 5D starts, the first step S31 is executed.

In the first step S31, it is determined by the input unit 41 and the touch controller 21 whether a touch input has been performed. If it is determined in the first step S31 that a touch input has not been performed (NO), then the second step S32 is executed. In contrast, if it is determined that a touch input has been performed (YES), then the third step S33 is executed.

In the second step S32, it is determined whether a predetermined time has elapsed since the most recent touch input, If it is determined that the predetermined time has not elapsed (NO), then the first step S31 is executed again. In contrast, if it is determined that the predetermined time has elapsed (YES), the sub-flowchart in FIG. 51) ends. At this time, because the use of the touch panel keyboard function is considered has ended, data such as the reference positions, the display sizes SX and SY, the adjusted keyboard image data, and the display position coordinates PX and PY may be reinitialized.

In the third step S33, the operation classifier 211 determines whether or not a parameter of the touch operation satisfies a predetermined condition. As an example, if the touch strength or touch area serving as the parameter of the touch operation exceeds the predetermined threshold (YES), the touch operation is considered to have been performed for the purpose of a key input. Consequently, the sixth step S36 is executed next. In contrast, if the touch strength or touch area serving as the parameter of the touch operation does not exceed the predetermined threshold (NO), the touch operation is considered to have been performed for the purpose of searching for a home position. Consequently, the fourth step S34 is executed next.

In addition, the purpose of the touch operation may be determined according to the number of consecutive times a touch operation is performed. For example, in the case of a single touch operation, in which just one touch is performed within a predetermined time, it may be determined that a search for a home position has been performed. In the case of a double touch operation, in which two touches are performed consecutively within a predetermined time and in a predetermined area, it may be determined that a key input has been performed. Further, for example, a double touch operation may be determined as a key input for only the home position keys, while a single touch operation may be determined as a key input for the other keys. In this case, the purpose of the touch operation may be determined based on the touch strength or the touch area as described above.

In the fourth step S34, the touch controller 21 calculates the distance from the touch position to a reference position. As an example, if a plurality of reference positions are stored, the reference position closest to the touch position may be selected, and the distance from the touch position to this reference position may be calculated. The fifth step S35 is executed following the fourth step S34.

In the fifth step S35, the vibration unit group 43 vibrates the input unit 41 according to a vibration pattern corresponding to the calculated distance under the control of the vibration controller 23. As an example, the vibration may be continued until the fingers of the user become separated from the input unit 41, or may be continued until the next touch operation is performed which has the purpose of a key input. Furthermore, as another example, if the calculated distance is greater than a predetermined distance, such as when a touch operation is performed at a location which is further away than another key which is adjacent to a home position key in the adjusted keyboard image 100, the vibration strength may be set to zero, the vibration strength may be weakened in inverse proportion to the distance, or the distance and the vibration strength may have a non-linear relationship. As yet another example, if the touch position is outside the adjusted keyboard image 100, the vibration strength may be set to zero, the vibration strength may be weakened based on the distance, or an alert may be issued to the user by conversely increasing the vibration strength or by employing a special vibration waveform. The first step S31 is executed again following the fifth step S35.

In the sixth step S36, the key identifier 213 identifies the key that corresponds to the touch position of the touch operation, Here, the vibration associated with a home position search may be stopped at the time the operation associated with the key input is started. The seventh step S37 is executed following the sixth step S36.

In the seventh step S37, the touch panel 10 inputs to the multifunction peripheral 1 a code corresponding to the identified key, in other words, a key signal representing the identified key is transmitted from the touch panel 10 to the multifunction peripheral 1. The eighth step S38 is executed following the seventh step S37.

In the eighth step S38, the touch panel 10 determines whether to end the touch panel keyboard operation. As an example, the touch panel keyboard function may be actively ended by the user performing a specific operation. The specific operation may be realized by performing a specific key input operation from the touch panel keyboard. It may also be realized by performing a touch operation in an area of the input unit 41 that corresponds to an image other than the keyboard image displayed on the display unit 42. It may also be performed by operating a button outside the touch panel 10 and provided on the multifunction peripheral 1. If it is determined that the touch panel keyboard operation is not to be ended (NO), the first step S31 is then executed again. In contrast, if it is determined that the touch panel keyboard operation is to be ended (YES), the sub-flowchart in FIG. 5D ends. At this time, because the use of the touch panel keyboard function is considered have been completed, data such as the reference positions, the display sizes SX and SY, the adjusted keyboard image data, and the display position coordinates PX and PY may be reinitialized.

When the sub-flowchart in FIG. 5D ends, the third step S03 of FIG. 5A ends, and the flowchart in FIG. 5A also ends.

According to the present embodiment of the present invention, the display sizes SX and SY of the adjusted keyboard image 100 can be changed according to the size of the user's hands. Furthermore, when a touch operation is performed near a home position of the adjusted keyboard image 100, by performing vibrational feedback using a vibration pattern that changes according to the distance from the home position to the touch position, the user is capable of searching tor the position of the home position using the sense of touch and not relying on the sense of vision. Therefore, the touch panel 10 according to the present embodiment of the present invention is capable of assisting touch typing input. This leads to a reduction in the input time associated with the touch panel keyboard function.

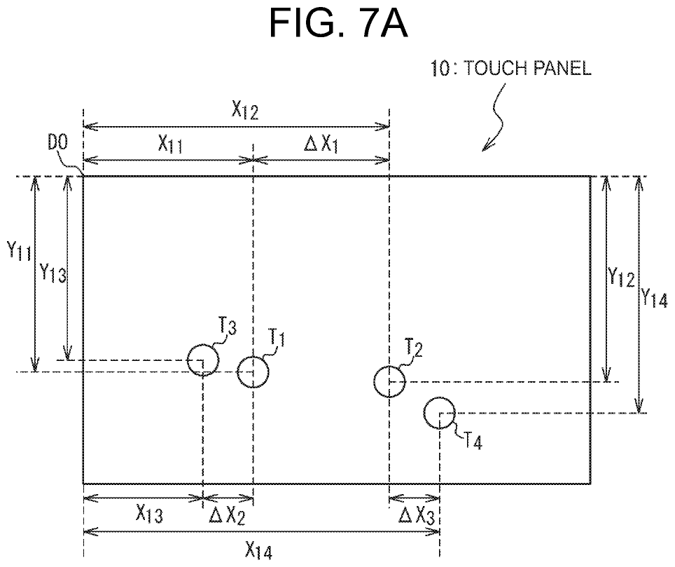

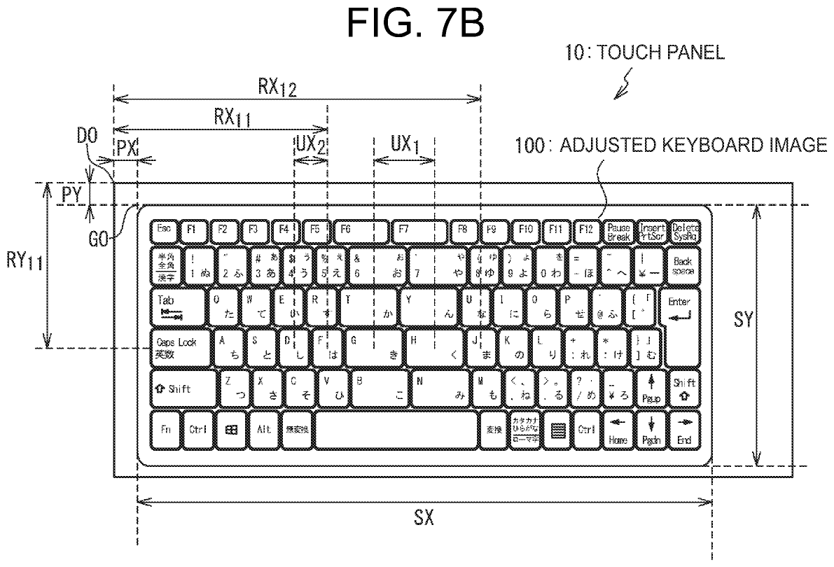

A modification of the reference positions and the display parameters of the keyboard image will be described with reference to FIG. 7A and FIG. 7B. FIG. 7A is a diagram showing another example of reference positions acquired according to an embodiment of the present invention. FIG. 7B is a diagram showing another example an adjusted keyboard image 100 displayed according to an embodiment of the present invention.

As shown in FIG. 7A, a total of four reference positions T₁ to T₄ are acquired in this modification. Similarly to the case of FIG. 6A, the first reference position T₁ corresponds to the forefinger of the left hand, and the second reference position T₂ corresponds to the forefinger of the right hand. Further, in FIG. 7A, the third reference position T₃ corresponds to the middle finger of the left hand, and the fourth reference position T₄ corresponds to the middle finger of the right hand. In terms of the coordinates of the touch panel 10, the third reference position T₃ has an X-axis coordinate X₁₃, and a Y-axis coordinate Y₁₃. In terms of the coordinates of the touch panel 10, the fourth reference position T₄ has an X-axis coordinate X₁₄, and a Y-axis coordinate Y₁₄.

As shown in FIG. 7B, two types of horizontal direction key pitches UX₁ and UX₂ are defined in the adjusted keyboard image 100 in this modification. That is to say, the first horizontal direction key pitch UX₁ represents a horizontal key pitch of the keys sandwiched between the home positions of the forefingers of both hands. The second horizontal key pitch UX₂ represents a horizontal key pitch of all of the remaining keys. The first horizontal direction key pitch UX₁ is applied to a central section of the keyboard in the horizontal direction, such as between “T” and “Y”, between “G” and “H”, and between “B” and N″. This means that in order for the image data adjuster 223 to generate the adjusted keyboard image 100, not only is the entire keyboard image before adjustment simply enlarged or reduced, but the scaling is different depending on the key to which the enlargement or reduction is applied.

More specifically, the second horizontal direction key pitch UX₂ is calculated based on an X-axis direction interval ΔX₂ between the first reference position T₁ and the third reference position T₃, and an X-axis direction interval ΔX₃ between the second reference position T₂ and the fourth reference position T₄. For example, the second horizontal direction key pitch UX₂ may be an average value of the interval ΔX₂ and the interval ΔX₃. As an example, the vertical direction key pitch UY₁ of all of the keys may be equal to the second horizontal direction key pitch UX₂.

The first horizontal direction key pitch UX₁ is calculated based on an X-axis direction interval ΔX₁ between the first reference position T₁ and the second reference position T₂, and the intervals ΔX₂ and ΔX₃. For example, the first horizontal direction key pitch UX₂ may be the difference between the interval ΔX₁ and the sum of the interval ΔX₂ and the interval ΔX₃. However, if the ratio or difference between the first horizontal direction key pitch UX₁ and the second horizontal direction key pitch UX₂ is greater than a predetermined threshold, it is determined that the condition has not been satisfied in the second step S12 of FIG. 5B, an alert is issued in the third step S13, and the acquisition of the reference positions T₁ to T₄ may be repeated in the first step S01 of FIG. 5A.

The home position of the forefinger of the left hand corresponding to the first reference position T₁ is the “F” key. The home position of the forefinger of the right hand corresponding to the second reference position T₂ is the “J” key. The home position of the middle finger of the left hand corresponding to the third reference position T₃ is the “D” key. The home position of the middle finger of the right hand corresponding to the fourth reference position T₄ is the “K” key. The Y-axis direction coordinate RY₁₁ of these four keys is the same. The coordinate RY₁₁ may be an average value of the Y-axis direction coordinates Y₁₁, Y₁₂, Y₁₃ and Y₁₄ of the four reference positions T₁ to T₄. However, if the difference between the coordinates Y₁₁, Y₁₂, Y₁₃ and Y₁₄ is greater than a predetermined threshold, such as when the angle between a virtual straight line passing through some or all of the reference positions T₁ to T₄ and the axis direction is larger than a predetermined threshold, it is determined that the condition has not been satisfied in the second step S12 of FIG. 5B, an alert is issued in the third step S13, and the acquisition of the reference positions T₁ to T₄ may be repeated in the first step S01 of FIG. 5A.

When these numerical values are obtained, the remaining display sizes SX and SY and display position coordinates PX and PY of the adjusted keyboard image 100 are uniquely obtained.

In the modification shown in FIG. 7A and FIG. 7B, the recognition accuracy of the home positions can be increased relative to the configuration example shown in FIG. 6A and FIG. 6B. Therefore, erroneous inputs into the touch panel keyboard can be further inhibited.

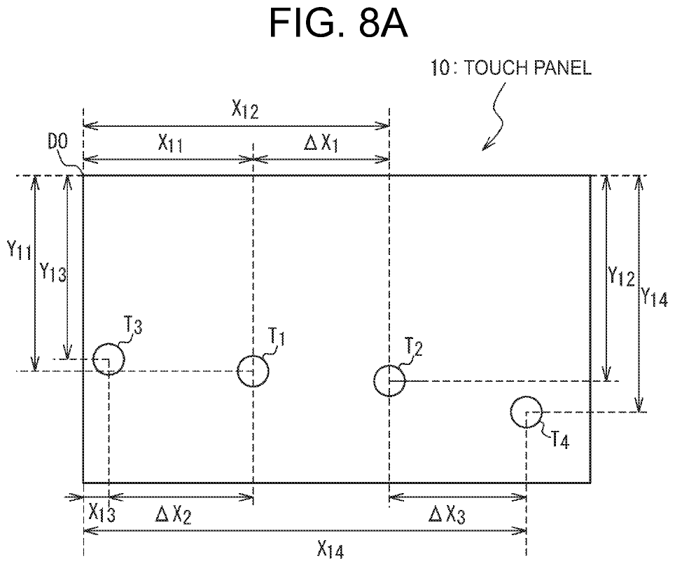

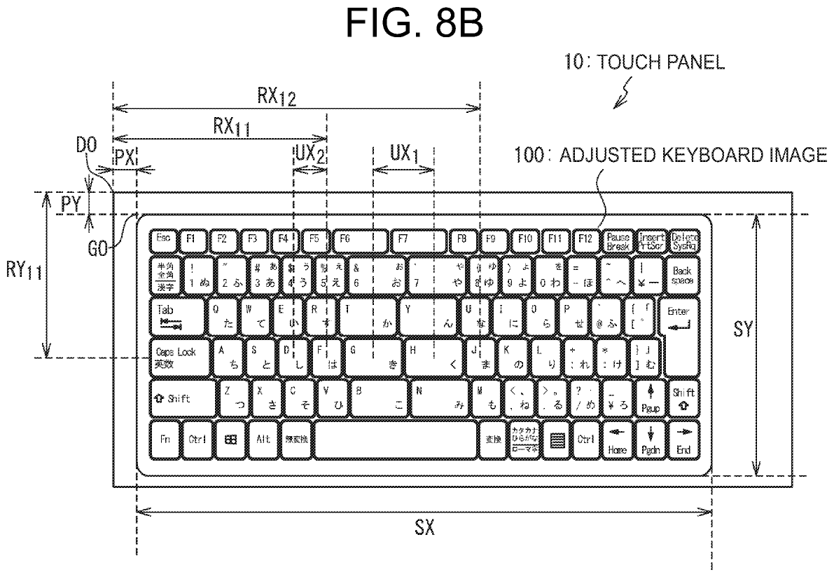

Another modification of the reference positions and the display parameters of the keyboard image will be described with reference to FIG. 8A and FIG. 8B. FIG. 8A is a diagram showing yet another example of reference positions acquired according to an embodiment of the present invention. FIG. 8B is a diagram showing yet another example an adjusted keyboard image 100 displayed according to an embodiment of the present invention.

As shown in FIG. 8A, a total of four reference positions T₁ to T₄ are acquired in this modification. Similarly to the case of FIG. 6A, the first reference position T₁ corresponds to the forefinger of the left hand, and the second reference position T₂ corresponds to the forefinger of the right hand. Further, in FIG. 8A, the third reference position T₃ corresponds to the little finger of the left hand, and the fourth reference position T₄ corresponds to the little finger of the right hand. In terms of the coordinates of the touch panel 10, the third reference position T₃ has an X-axis coordinate X₁₃, and a Y-axis coordinate Y₁₃. In terms of the coordinates of the touch panel 10, the fourth reference position T₄ has an X-axis coordinate X₁₄, and a Y-axis coordinate Y₁₄. Although only the forefinger and the little finger of both hands are focused on here, the touch positions of the middle fingers and the index fingers may also be additionally acquired at the same time. In other words, a total of eight reference positions that respectively correspond to the eight fingers other than the thumbs of both hands may all be acquired.

As shown in FIG. 8B, two types of horizontal direction key pitches UX₁ and UX₂ are defined in the adjusted keyboard image 100 in this modification. That is to say, the first horizontal direction key pitch UX₁ represents a horizontal key pitch of the keys sandwiched between the home positions of the forefingers of both hands. The second horizontal key pitch UX₂ represents a horizontal key pitch of all of the remaining keys. The first horizontal direction key pitch UX₁ is applied, for example, between “T” and “Y”, between “G” and “H”, and between “B” and N”. This means that in order for the image data adjuster 223 to generate the adjusted keyboard image 100, not only is the entire keyboard image before adjustment simply enlarged or reduced, but the scaling is different depending on the key to which the enlargement or reduction is applied.

More specifically, the second horizontal direction key pitch UX₂ is calculated based on an X-axis direction interval ΔX₂ between the first reference position T₁ and the third reference position T₃, and an X-axis direction interval ΔX₃ between the second reference position T₂ and the fourth reference position T₄. For example, the second horizontal direction key pitch UV) may be one-third of the average value of the interval ΔX₂ and the interval ΔX₃. As an example, the vertical direction key pitch UY₁ of all of the keys may be equal to the second horizontal direction key pitch UX₂, or may be calculated as the product of the horizontal key pitch UX₂ multiplied by a predetermined ratio. Furthermore, as another example, if eight reference positions are acquired, the vertical direction key pitch UYI may be calculated based on an upper limit value and a lower limit value of the Y-axis direction coordinates of the eight reference positions.

The first horizontal direction key pitch UX₁ is calculated based on an X-axis direction interval ΔX₁ between the first reference position T₁ and the second reference position T2, and the intervals ΔX₂ and ΔX₃. For example, the first horizontal direction key pitch UX₁ may be the difference between the interval ΔX₁ and the sum of the interval ΔX₂ and the interval ΔX₃. However, if the ratio or difference between the first horizontal direction key pitch UX₁ and the second horizontal direction key pitch UX₂ is greater than a predetermined threshold, it is determined that the condition has not been satisfied in the second step S12 of FIG. 5B, an alert is issued in the third step S13, and the acquisition of the reference positions T₁ to T₄ may be repeated in the first step S01 of FIG. 5A.

The home position of the forefinger of the left hand corresponding to the first reference position T₁ is the “F” key. The home position of the forefinger of the right hand corresponding to the second reference position T₂ is the “J” key. The home position of the little finger of the left hand corresponding to the third reference position T₃ is the “A” key. The home position of the little finger of the right hand corresponding to the fourth reference position T₄ is the “;” key, The Y-axis direction coordinate RY₁₁ of these four keys is the same. The coordinate RY₁₁ may be an average value of the Y-axis direction coordinates Y₁₁, Y₁₂, Y₁₃ and Y₁₄ of the four reference positions T₁ to T₄. However, if the difference between the coordinates Y₁₁, Y₁₂, Y₁₃ and Y₁₄ is greater than a predetermined threshold, such as when the angle between a virtual straight line passing through some or all of the reference positions T₁ to T₄ and the Y axis direction is larger than a predetermined threshold, it is determined that the condition has not been satisfied in the second step S12 of FIG. 5B, an alert is issued in the third step S13, and the acquisition of the reference positions T₁ to T₄ may be repeated in the first step S01 of FIG. 5A.

When these numerical values are obtained, the remaining display sizes SX and SY and display position coordinates PX and PY of the adjusted keyboard image 100 are uniquely obtained.

In the modification shown in FIG. 8A and FIG. 8B, the recognition accuracy of the home positions can be increased relative to the modification shown in FIG. 7A and. FIG. 7B. Therefore, erroneous inputs into the touch panel keyboard can be further inhibited.

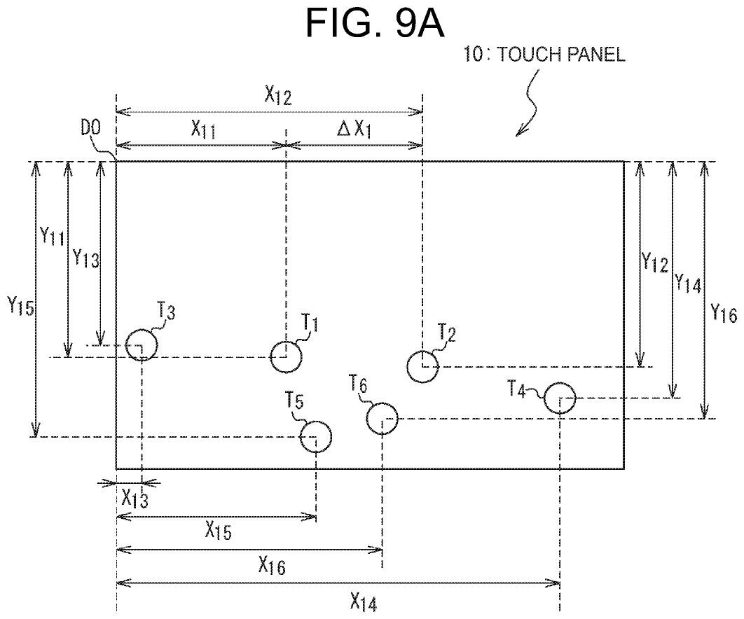

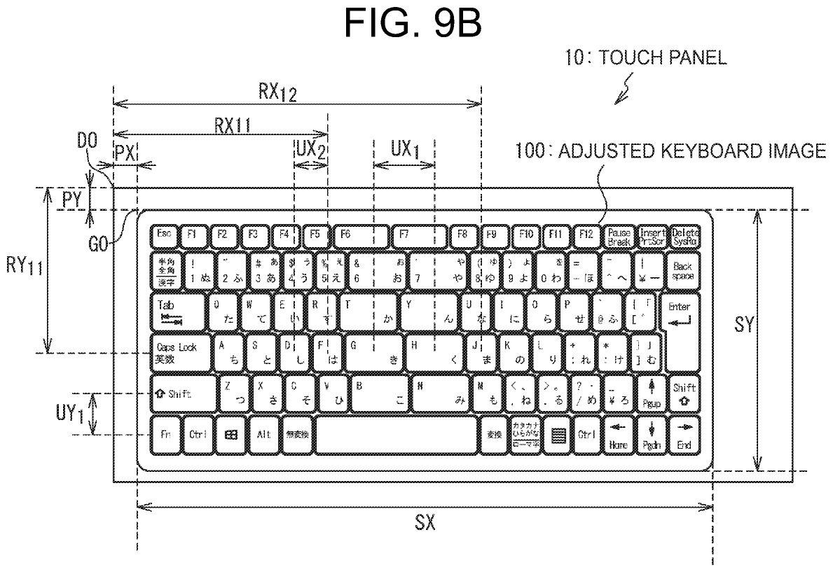

Yet another modification of the reference positions and the display parameters of the keyboard image will be described with reference to FIG. 9A and FIG. 9B. FIG. 9A is a diagram showing yet another example of a reference position acquired according to an embodiment of the present invention. FIG. 9B is a diagram showing yet another example an adjusted keyboard image 100 displayed according to an embodiment of the present invention.

As shown in FIG. 9A, a total of six reference positions T₁ to T₆, are acquired in this modification. Similarly to the case of FIG. 8A, the first reference position T₁ corresponds to the forefinger of the left hand, the second reference position T₂ corresponds to the forefinger of the right hand, the third reference T₃ position corresponds to the little finger of the left hand, and the fourth reference position T₄ corresponds to the little finger of the right hand. Further, in FIG. 9A, the fifth reference position T₅ corresponds to the thumb of the left hand, and the sixth reference position To corresponds to the thumb of the right hand, In terms of the coordinates of the touch panel 10, the fifth reference position T₅ has an X-axis coordinate X₁₅, and a Y-axis coordinate Y₁₅. In terms of the coordinates of the touch panel 10, the sixth reference position To has an X-axis coordinate X₁₆, and a Y-axis coordinate Y₁₆. Although only the forefinger, the little finger, and the thumb of both hands are focused on here, the touch positions of the middle fingers and the index fingers may also additionally be acquired at the same time. In other words, a total of ten reference positions that respectively correspond the ten fingers of both hands may all be acquired.

As shown in FIG. 9B, two types of horizontal direction key pitches UX₁ and UX₂ are defined in the adjusted keyboard image 100 in this modification. The definition and calculation method of the horizontal direction key pitches UX₁ and UX₂ are the same as in the case of FIG. 8B. Therefore, a more detailed explanation is omitted.

In the modification in FIG. 9B, a vertical direction key pitch UY₁ is further defined. The first vertical direction key pitch UY₁ can be calculated based on the Y-axis direction coordinates Y₁₁ to Y₁₆ of the first reference position T₁ to the sixth reference position T₆. For example, the vertical direction key pitch UY₁ may be calculated as one-half of the difference between the average value of the coordinates Y₁₁ to Y₁₄ and the average value of the coordinates Y₁₅ and Y₁₆.

In the modification shown in FIG. 9A and FIG. 9B, the recognition accuracy of the home positions can be increased relative to the modification shown in FIG. 8A and FIG. 8B, particularly in the vertical direction of the keyboard. Therefore, erroneous inputs into the touch panel keyboard can be further inhibited.

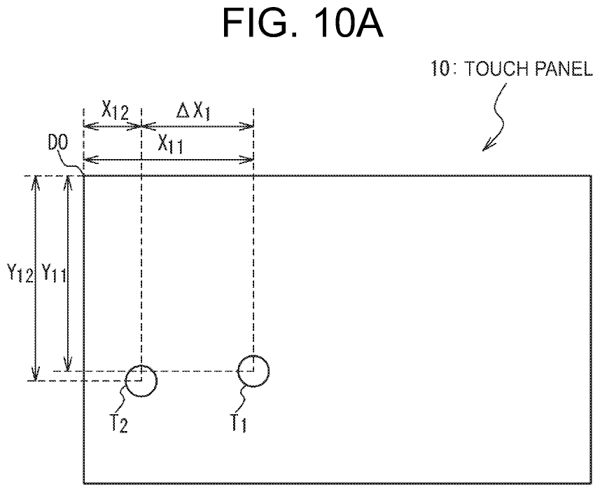

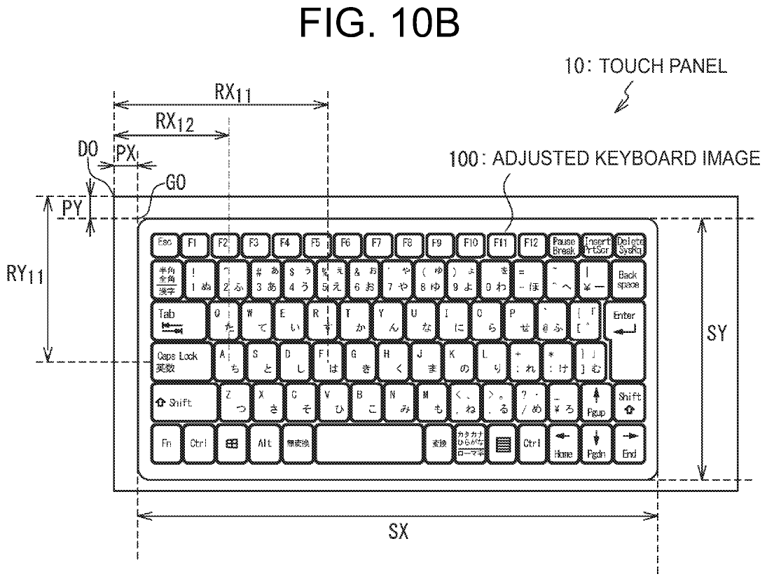

Yet another modification of the reference positions and the display parameters of the keyboard image will be described with reference to FIG. 10A and FIG. 10B. FIG. 10A is a diagram showing yet another example of reference positions acquired according to an embodiment of the present invention. FIG. 10B is a diagram showing yet another example an adjusted keyboard image 100 displayed according to an embodiment of the present invention.

As shown in FIG. 10A, a total of two reference positions T₁ and T₂ are acquired in this modification. Similarly to the case of FIG. 6A, the first reference position T₁ corresponds to the forefinger of the left hand. However, the second reference position T₂ corresponds to the little finger of the left hand. In other words, in this modification, the acquisition of the reference positions T₁ and T₂ is performed using just one hand.

As shown in FIG. 10B, in this modification, the same adjusted keyboard image 100 as the case of FIG. 6B is displayed as the adjusted keyboard image 100 on the touch panel 10. However, the display sizes SX and SY and display position coordinates PX and PY of the adjusted keyboard image 100 are calculated based on the coordinates of the reference positions T₁ and T₂. More specifically, the position at which the “F” key is displayed, which is the home position of the forefinger of the left hand, and the position at which the “A” key is displayed, which is the home position of the little finger of the left hand, are calculated based on the reference positions T₁ and T₂. Then, the display sizes SX and SY and display position coordinates PX and PY of the adjusted keyboard image 100 can be calculated based on these display positions.

In the modification shown in FIG. 10A and FIG. 1013, the acquisition of the reference positions can be simplified relative to the configuration example shown in FIG. 6A and FIG. 6B.

In the description above, an example is described in which, when the most recent touch operation is a home position search operation, the vibration pattern used by the vibration unit 43 to vibrate the input unit 41 and the display unit 42 is selected and. determined from among a plurality of vibration patterns based on the distance from the touch position to the home position, However, the present invention is not limited to this example. That is to say, the vibration pattern may be selected and determined based on the direction from the touch position to the home position instead of the distance. Furthermore, the vibration pattern may be selected and determined based a combination of the distance and the direction.

Even when the vibration pattern is selected and determined from among a plurality of vibration patterns according to only the distance from the touch position to the home position, it is possible for the user to estimate the direction to the home position from the current touch position from the changing nature of the vibration pattern according to the distance, by performing a motion in which the touch operation is repeated a plurality of times, or by performing the motion of sliding a finger while touching the input unit 41. In other words, it is possible for the position of the home position to be estimated.

The touch panel 10 described above and the multifunction peripheral 1 provided with the same may be realized by hardware, software, or a combination thereof. Furthermore, the control method of the touch panel 10 described above may be realized by hardware, software, or a combination thereof. Here, being realized by software refers to being realized by a computer reading and executing a program.

The program may be stored using various types of non-transitory computer readable media, and supplied to a computer. Non-transitory computer readable media include various types of tangible storage media.

Examples of non-transitory computer readable media include a magnetic recording medium (such as a flexible disk, magnetic tape, and a hard disk drive), a magneto-optical recording medium (such as a magneto-optical disk), a compact disc read-only memory (CD-ROM), a compact disc-recordable (CD-R), a compact disc-rewritable (CD-R/W), a semiconductor memory (such as a mask ROM, a programmable ROM (PROM), an erasable PROM (EPROM), a flash ROM, and a random access memory (RAM).

Furthermore, the program may he supplied to a computer by various types of transitory computer readable media.

Examples of transitory computer readable media include electrical signals, optical signals, and electromagnetic waves.

Transitory computer readable media are capable of supplying the program to a computer via a wired communication path such as an electric wire or an optical fiber, or a wireless communication path.

The present invention may be implemented in various other forms without departing from the spirit or essential characteristics thereof. Therefore, each of the embodiments described above are merely examples, and should not be construed as limiting. The scope of the present invention is represented by the scope of claims, and is not limited by the text of the specification. Further, all modifications and changes belonging to a scope equivalent to the claims are within the scope of the present invention.

The present invention can be utilized in a touch panel 10 and a control method of the touch panel 10. Furthermore, the touch panel 10 provided in the multifunction peripheral 1 has been mainly described here. However, the present invention is also applicable to other terminals having an input unit 41, a display unit 42, and a vibration unit 43, such as notebook PC terminals, tablet terminals, and smartphone terminals.

### BRIEF DESCRIPTION OF THE REFERENCE SYMBOLS

1 Multifunction peripheral
10 Touch panel
20 Controller
21 Touch controller
211 Operation classifier
212 Touch position acquirer
213 Key identifier
22 Display controller
221 Reference position storage device
222 Display size calculator
223 Image data adjuster
224 Display position calculator
23 Vibration controller
231 Vibration pattern_{—} controller
30 Control circuit device
31 High-voltage generation circuit
32 Filter circuit
33 Amplifier circuit
40 I/O module
41 Input unit
42 Display unit
43, 43A, 43B Vibration unit
51 Bus
52 interface
53 Calculator
54 Storage
541 Program
542 Data
55 External recording medium
100 Adjusted keyboard image

What is claimed is:

1. A touch panel comprising:
a display device;
an input device that accepts a touch operation made with respect to the display device;
a vibration device that vibrates the display device; and
a controller that controls the display device, the input device, and the vibration device; wherein
the controller includes
a display controller hat displays a predetermined keyboard image on the display device, and
a vibration controller that selects, when a most recent touch operation is a home position search operation, based on a relative positional relationship between a touch position on the display device at which the most recent touch operation is received and a first home position set on the predetermined keyboard image, a vibration pattern from among a plurality of vibration patterns that differ according to the relative positional relationship as a first vibration pattern, and vibrates the display device via the vibration device by the first vibration pattern.

2. The touch panel according to claim 1, wherein
the relative positional relationship between the touch position on the display device at which the most recent touch operation is received and the first home position set on the predetermined keyboard image is a distance from the first home position to the touch position, a direction from the first home position to the touch position, or a combination thereof.

3. The touch panel according to claim 1, wherein
the plurality of vibration patterns include a plurality of vibration patterns in which any one of a vibration amplitude, a vibration waveform, or a vibration frequency, or a combination thereof, is adjusted according to the relative positional relationship.

4. The touch panel according to claims 1, wherein
the vibration controller controls the vibration device such that, if a vibration by the first vibration pattern is being continued when a most recent touch operation is a key input operation, the vibration by the first vibration pattern is stopped.

5. The touch panel according to claims 1, wherein
the controller further includes:
a touch operation classification device that classifies, based on whether or not a predetermined parameter relating to the touch operation satisfies a predetermined criteria, the touch operation as either a key input operation that touches a key included in the predetermined keyboard image, or a home position search operation that searches for a home position set in the keyboard image; and
the predetermined parameter includes at least one of a strength, touch area, or consecutive frequency of the touch operation.

6. The touch panel according to claim 1, wherein
the predetermined keyboard image is further set with a second home position at a different position to the first home position, and
the vibration controller selects, when a most recent touch operation is a home position search operation, based on a relative positional relationship between the touch position on the display device at which the most recent touch operation is received and the second home position set on the predetermined keyboard image, a vibration pattern from among a plurality of vibration patterns that differ according to the relative positional relationship as a second vibration pattern, and further vibrates the display device via the vibration device by the second vibration pattern.

7. The touch panel according to claim 1, wherein
the vibration device includes
a first vibration device that vibrates the display device by the first vibration pattern under a control of the vibration controller, and
a second vibration device that vibrates the display device by the second vibration pattern under the control of the vibration controller from a different position to the first vibration device,
the predetermined keyboard image is further set with a second home position at the different position to the first home position, and
the vibration controller selects, when a most recent touch operation is a home position search operation, based on a relative positional relationship between the touch position on the display device at which the most recent touch operation is received and the second home position set on the predetermined keyboard image, a vibration pattern from among a plurality of vibration patterns that differ according to the relative positional relationship as a second vibration pattern, and further vibrates the display device via the second vibration device by the second vibration pattern.

8. The touch panel according to claim 7, wherein
the relative positional relationship between the touch position on the display device at which the most recent touch operation is received and the second home position set on the predetermined keyboard image is a distance from the second home position to the touch position, a direction from the second home position to the touch position, or a combination thereof.

9. The touch panel according to claim 1, wherein
the controller further includes
a reference position storage device that stores two touch positions as a first reference position and a second reference position at which the input device is received a touch operation in a state prior to the predetermined keyboard image being displayed on the display device,
a display size calculator that calculates a display size in which the predetermined keyboard image is displayed on the display device based on the first reference position and the second reference position,
an image data generator that generates the predetermined keyboard image so as to fit the display size,
a display position calculator that calculates a display position at which the predetermined keyboard image is displayed on the display device based on the first reference position and the second reference position, and
a key identifier that identifies, when the most recent key operation is a key input operation, a key within the predetermined keyboard image displayed on the display device which is displayed at a touch position in which the input device is accepted a touch operation, based on the touch position, the display size, and the display position.

10. The touch panel according to claim 9, wherein
the first reference position is a home position of a forefinger of one hand of a user,
the second reference position is a home position of a forefinger of a different hand of the user, and
the display size calculator calculates a horizontal direction key pitch in the predetermined keyboard image based on a first interval from the first reference position to the second reference position.

11. The touch panel according to claim 9, wherein
the reference position storage device further stores, in addition to the two touch positions, two additional touch positions as a third reference position and a fourth reference position respectively at which the input device receives a touch operation in a state prior to the predetermined keyboard image being displayed on the display device,
the first reference position is a home position of a forefinger of one hand of a user,
the second reference position is a home position of a forefinger of a different hand of the user,
the third reference position is a home position of a middle finger of the one hand of the user,
the fourth reference position is a home position of a middle finger of the different hand of the user, and
the display size calculator
calculates a first horizontal direction key pitch at a central section of the predetermined keyboard image based on a first interval from the first reference position to the second reference position, a second interval from the first reference position to the third reference position, and a third interval from the second reference position to the fourth reference position, and
calculates a second horizontal direction key pitch of a section other than the central section of the predetermined keyboard image based on the second interval and the third interval.

12. The touch panel according to claim 9, wherein
the reference position storage device further stores, in addition to the two touch positions, two additional touch positions as a third reference position and a fourth reference position at which the input device receives a touch operation in a state prior to the predetermined keyboard image being displayed on the display device,
the first reference position is a home position of a forefinger of one hand of a user,
the second reference position is a home position of a forefinger of a different hand of the user,
the third reference position is a home position of a little finger of the one hand of the user,
the fourth reference position is a home position of a little finger of the different hand of the user, and
the display size calculator
calculates a first horizontal direction key pitch at a central section of the predetermined keyboard image based on a first interval from the first reference position to the second reference position, a second interval from the first reference position to the third reference position, and a third interval from the second reference position to the fourth reference position, and
calculates a second horizontal direction key pitch of a section other than the central section of the predetermined keyboard image based on the second interval and the third interval.

13. The touch panel according to claim 9, wherein
the reference position storage device further stores, in addition to the two touch positions, four additional touch positions as a third reference position to a sixth reference position at which the input device receives a touch operation in a state prior to the predetermined keyboard image being displayed on the display device,
the first reference position is a home position of a forefinger of one hand of a user,
the second reference position is a home position of a forefinger of the different hand of the user,
the third reference position is a home position of a Tittle finger of the one hand of the user,
the fourth reference position is a home position of a little finger of a different hand of the user,
the fifth reference position is a home position of a thumb of the one hand of the user, and
the sixth reference position is a home position of a thumb of the different hand of the user, and
the display size calculator
calculates a first horizontal direction key pitch at a central section of the predetermined keyboard image based on a first interval from the first reference position to the second reference position, a second interval from the first reference position to the third reference position, and a third interval from the second reference position to the fourth reference position,
calculates a second horizontal direction key pitch of a section other than the central section of the predetermined keyboard image based on the second interval and the third interval, and
calculates a vertical direction key pitch of the predetermined keyboard image based on a vertical direction coordinate from the first reference position to the sixth reference position.

14. The touch panel according to claim 9, wherein
the first reference position is a home position of a forefinger of one hand of a user,
the second reference position is a home position of a little finger of the one hand of the user, and
the display size calculator calculates a horizontal direction key pitch in the predetermined keyboard image based on a first interval from the first reference position to the second reference position.

15. The touch panel according to claim 1, wherein the vibration device includes a piezoelectric element that vibrates according to an electric signal corresponding to the first vibration pattern.

16. A control method of a touch panel including a display device, an input device that accepts a touch operation made with respect to the display device, and a vibration device that vibrates the display device, the method comprising:
displaying a predetermined keyboard image on the display device, and
selecting, when a most recent touch operation is a home position search operation, based on a relative positional relationship between a touch position on the display device at which the most recent touch operation is received and a first home position set on the predetermined keyboard image, a vibration pattern from among a plurality of vibration patterns that differ according to the relative positional relationship as a first vibration pattern, and vibrating the display device via the vibration device by the first vibration pattern.
